(19) United States
(12) Patent Application Publication
(10) Pub. No.: US 2026/0188223 A1
(43) Pub. Date: Jul. 2, 2026

(54) DISPLAY APPARATUS

(71) Applicant: LG Display Co., Ltd., Seoul (KR)

(72) Inventors: Dong Ho CHOI, Paju-si (KR); Ha Ye KIM, Paju-si (KR)

(73) Assignee: LG Display Co., Ltd., Seoul (KR)

(21) Appl. No.: 19/373,042

(22) Filed: Oct. 29, 2025

(30) Foreign Application Priority Data
Dec. 31, 2024 (KR) 10-2024-0201527

(51) Int. Cl. G09G 3/3233; H10K 59/121; H10K 59/131

(52) U.S. Cl. CPC G09G 3/3233; H10K 59/1213; H10K 59/131; G09G 2300/0426; G09G 2300/0819; G09G 2300/0842; G09G 2300/0861; G09G 2320/0223; G09G 2320/0233; G09G 2320/0242

(57) ABSTRACT

In present disclosure, a single common line is connected to supply an anode reset voltage to each sub-pixel, which may eliminate the need to add a separate voltage line within the display area; and an auxiliary capacitor is arranged between the anode and the cathode of the light-emitting element in at least one sub-pixel among the plurality of sub-pixels, which may compensate for the anode reset voltage.

### CROSS-REFERENCE TO RELATED APPLICATION

This application claims priority to and the benefit of Korean Patent Application No. 10-2024-0201527, filed December 31, 2024, the disclosure of which is incorporated herein by reference in its entirety.

### BACKGROUND

### Technical Field

The present disclosure relates to an apparatus and particularly to, for example, without limitation, a display apparatus, and more particularly, to a display apparatus capable of resetting an anode with an optimal voltage for each sub-pixel.

### Description of the Related Art

Image display apparatuses, which implement various information on a screen, are core technologies in the information and communication era and are developing towards being thinner, lighter, more portable, and high-performance. Accordingly, display apparatuses that may be manufactured to be lightweight and thin are gaining prominence.

Specific examples of such flat panel display apparatuses include a liquid crystal display apparatus (LCD), a quantum dot display apparatus (QD), a field emission display apparatus (FED), and an organic light-emitting diode (OLED) device, and the like.

Among these various display apparatuses, an organic display apparatus is a self-emission display apparatus. Unlike a liquid crystal display apparatus, it does not require a separate light source, allowing it to be manufactured to be lightweight and thin. Furthermore, an organic display apparatus is advantageous in terms of power consumption due to low-voltage driving, and also exhibits excellent color reproduction, response speed, viewing angle, and contrast ratio (CR), making it a subject of research for displays.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### BRIEF SUMMARY

The present disclosure provides a display apparatus capable of resetting an anode to an optimal voltage for each sub-pixel.

The present disclosure provides a display apparatus capable of supplying an optimal anode reset voltage to each sub-pixel without adding a separate voltage line within a display area.

The present disclosure provides a display apparatus capable of compensating for an anode reset voltage. The objects of the present disclosure are not limited to the above-mentioned objects, and other unmentioned objects will be clearly understood by those skilled in the art from the following description.

A display apparatus according to an embodiment of the present disclosure includes: a display panel including a display area in which a plurality of sub-pixels of different colors are arranged and a non-display area surrounding the display area; a light-emitting element arranged in each of the plurality of sub-pixels and including an anode and a cathode; and a common reset voltage line connected to the anode to transmit a common anode reset voltage to each of the plurality of sub-pixels, wherein at least one sub-pixel among the plurality of sub-pixels includes an auxiliary capacitor.

Other specific details of the embodiment are set forth in the detailed description and drawings.

According to the present disclosure, the anode may be reset with an optimal voltage for each sub-pixel, thereby improving electro-optical characteristics.

According to the present disclosure, an optimal anode reset voltage may be supplied to each sub-pixel through a single common line that is connected to supply the anode reset voltage for each sub-pixel, thereby eliminating the need to add a separate voltage line within a display area.

According to the present disclosure, an auxiliary capacitor may be arranged between the anode and a low-potential driving voltage line in at least one sub-pixel among the plurality of sub-pixels, thereby compensating for the anode reset voltage.

The effects according to the present disclosure are not limited by the examples described above, and various other effects are included herein.

It is to be understood that both the foregoing general description and the following detailed description are exemplary and explanatory and are intended to provide further explanation of the inventive concepts and the claims.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a block diagram illustrating a display apparatus according to an embodiment of the present disclosure;

FIG. 2 is a circuit diagram of a sub-pixel included in the display apparatus according to an embodiment of the present disclosure;

FIG. 3 is a cross-sectional view illustrating a partial area around a light-emitting element of the display apparatus according to an embodiment of the present disclosure;

FIG. 4 is a plan view illustrating a plurality of sub-pixels included in a pixel shown in FIG. 1;

FIG. 5 is a layout view illustrating a common reset voltage line of the display apparatus according to an embodiment of the present disclosure;

FIG. 6 is a layout view illustrating a circuit configuration of a plurality of sub-pixels and a common reset voltage line, in the display apparatus according to an embodiment of the present disclosure;

FIGS. 7A and 7B are drawings illustrating a plurality of sub-pixels arranged in a pixel row, in the display apparatus according to an embodiment of the present disclosure;

FIG. 8 is a cross-sectional view illustrating a partial area around a fourth node of the display apparatus according to an embodiment of the present disclosure;

FIGS. 9A and 9B are plan views illustrating a plurality of sub-pixels according to another embodiment of the present disclosure;

FIG. 10 is a simulation result for driving voltages according to Comparative Example 1, Comparative Example 2, and an embodiment of the present disclosure; and

FIG. 11 is a simulation result comparing data ranges of Comparative Example 2 and an embodiment of the present disclosure to confirm changes in low gray-scale image quality.

### DETAILED DESCRIPTION

The advantages and features of the present disclosure and methods for accomplishing the same will be more clearly understood from embodiments described below with reference to the accompanying drawings. However, the present disclosure is not limited to the following embodiments but can be implemented in various different forms. Rather, the present embodiments will make the disclosure of the present disclosure complete and allow those skilled in the art to completely comprehend the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the present disclosure. Further, in describing the present disclosure, detailed descriptions of known related technologies can be omitted to avoid unnecessarily obscuring the subject matter of the present disclosure.

The terms such as “comprising,” “including,” “having,” and “containing” used herein are generally intended to allow other components to be added unless the terms are used with the term “only.” Any references to singular can include plural unless expressly stated otherwise.

Components are interpreted to include an ordinary error range even if not expressly stated.

When a positional or interconnected relationship is described between two components, such as “on top of,” “above,” “below,” “next to,” “connect or couple with,” “crossing,” “intersecting,” or the like, one or more other components can be interposed between them, unless “immediately” or “directly” is used.

When a temporal antecedent relationship is described, such as “after,” “following,” “next to,” “before,” or the like, it may not be continuous on a time base unless “immediately” or “directly” is used.

The terms “first,” “second,” and the like can be used to distinguish elements from each other, but the functions or structures of the components are not limited by ordinal numbers or component names in front of the components, and may not define order or sequence. Further, the term “can” fully encompasses all the meanings and coverages of the term “may” and vice versa.

The following embodiments can be partially or entirely bonded to or combined with each other and can be linked and operated in technically various ways. The embodiments can be carried out independently of or in association with each other.

Any implementation described herein as an “example” is not necessarily to be construed as preferred or advantageous over other implementations.

Also, when an element or layer is “connected,” “coupled,” or “adhered” to another element or layer denotes that the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various embodiments of the present disclosure will be described in detail with reference to the accompanying drawings.

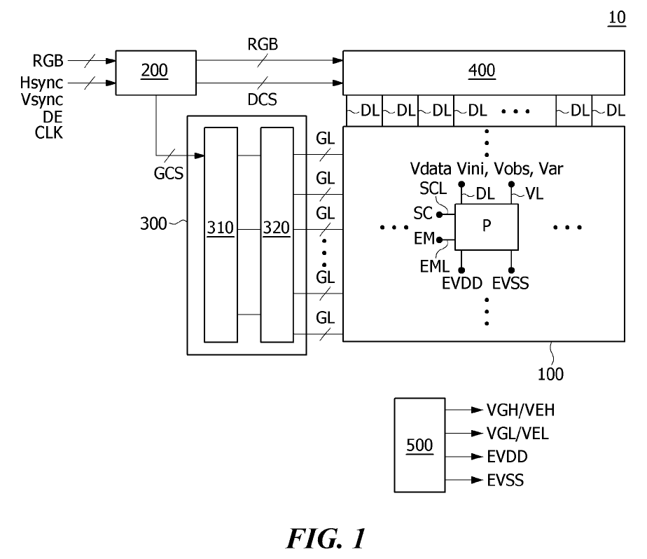

FIG. 1 is a block diagram illustrating a display apparatus according to an embodiment of the present disclosure.

As shown in FIG. 1, the display apparatus 10 according to the embodiment of the present disclosure may include a display panel 100, a data driving circuit 400, a gate driving circuit 300, a power supply 500, and a timing controller 200.

The display panel 100 may have a plurality of pixels P arranged thereon. The plurality of pixels P may be arranged in areas where a plurality of data lines DL and/or a plurality of gate wires GL intersect. Pixels P arranged in the same horizontal line may form one pixel row. Pixels P arranged in one pixel row are connected to one gate wire GL, and the one gate line GL may include at least one scan line and at least one emission line. For example, each pixel P may be connected to one data line DL, and the at least one scan line and the at least one emission line, but embodiments of this specification are not limited thereto.

The data driving circuit 400 may drive the data lines DL. The gate driving circuit 300 may drive the gate wires GL. The power supply 500 may supply power for driving each of the plurality of pixels P.

The plurality of pixels P may commonly receive a high-potential driving voltage ELVDD, a low-potential driving voltage ELVSS, and the like from the power supply 500. The plurality of pixels P may receive a bias voltage Vobs and initialization voltages VAR and Vini from a power supply line VL. The bias voltage Vobs may be supplied to the plurality of pixels P from a bias voltage wire VobsL among the power lines VL, and an anode reset voltage VAR may be supplied to the plurality of pixels P from a common reset voltage line among the power lines VL.

Thin film transistors (TFTs) forming the pixel P may be implemented with oxide TFTs including an oxide semiconductor layer. The oxide TFT may be advantageous in increasing the area of the display panel 100 in consideration of all electron mobility and process deviation. The present disclosure is not limited to this, and the semiconductor layer of the TFT may also be formed of amorphous silicon or poly-silicon, or the like.

Each pixel P may include a light-emitting element (organic light-emitting diode (OLED), a driving TFT for supplying current to the light-emitting element, a switching TFT for supplying a data voltage to the driving TFT, and a storage capacitor for charging the data voltage supplied to the driving TFT. The storage capacitor may maintain the data voltage during one frame.

Each pixel P may further include a plurality of TFTs and a storage capacitor to compensate for changes in the threshold voltage of the driving TFT.

Touch sensors may be arranged in the display panel 100. Touch input may be sensed using separate touch sensors or through pixels P. The touch sensors may be arranged as an On-cell type or an Add on type on the screen of the display panel 100 or implemented as In-cell type touch sensors embedded in the pixel array.

The timing controller 200 may control the driving timing of the data driving circuit 400 and the gate driving circuit 300. The timing controller 200 may rearrange digital video data RGB input from the outside to match the resolution of the display panel 100 and supply it to the data driving circuit 400.

In addition, the timing controller 200 may generate a data control signal DCS for controlling the operation timing of the data driving circuit 400 and a gate control signal GCS for controlling the operation timing of the gate driving circuit 300 based on timing signals such as a vertical synchronization signal Vsync, a horizontal synchronization signal Hsync, a dot clock signal CLK, and a data enable signal DE.

The data driving circuit 400 may convert digital video data RGB input from the timing controller 200 into analog data voltage based on the data control signal DCS and provide it to each data line DL.

The data driving circuit 400 may include one or more source drive ICs (SIC). The source drive IC may convert digital video data of an input image into an analog gamma compensation voltage under the control of the timing controller 200 to generate a data voltage and output the data voltage to data lines DL. The source drive IC may be mounted on a flexible circuit board, for example, a COF (Chip on Film), or may be directly bonded onto a substrate of a non-display area of the display panel 100 using a COG process.

COFs may be bonded to pad areas of the display panel 100 and a source PCB through an anisotropic conductive film (ACF). Input pins of the COFs may be electrically connected to output terminals (pads) of the source PCB. Output pins of the source COFs may be electrically connected to data pads formed on a substrate of the display panel 100 through the ACF.

In FIG. 1, the data driving circuit 400 is illustrated as being arranged one on one side of the display panel 100, but the number and arrangement positions of the data driving circuits 400 are not limited thereto. For example, the data driving circuit 400 may be formed of a plurality of integrated circuits (ICs), and the plurality of integrated circuits may be arranged separately on one side of the display panel 100.

The gate driving circuit 300 may generate a scan signal and an emission signal based on the gate control signal GCS. The gate driving circuit 300 may include at least one scan driver 310 and an emission driver 320.

The at least one scan driver 310 may generate a scan signal SC in a row-sequential manner and supply it to gate wires GL to drive at least one scan line SCL connected to each pixel row. The at least one scan driver 310 may output a scan pulse in response to a start pulse and a shift clock from the timing controller 200, and may shift the scan pulse in accordance with the shift clock timing.

The emission driver 320 may generate an emission control signal EM in a row-sequential manner and supply it to the emission lines to drive at least one emission line EML connected to each pixel row. The emission driver 320 may output an emission control signal pulse in response to the start pulse and the shift clock from the timing controller 200, and sequentially shift the emission control signal pulse according to the shift clock.

The scan signal SC may include a scan pulse that swings between a gate-on voltage VGL and a gate-off voltage VGH. The emission control signal EM may include an emission control signal pulse that swings between a gate-on voltage VEL and a gate-off voltage VEH. The scan pulse may select pixels P of a line to which a data voltage Vdata is to be written. The emission control signal EM may define an emission time of the pixels P.

The gate wire GL may supply the scan signal SC and the emission control signal EM to the plurality of pixels P, and the data line DL may supply the data voltage Vdata to the plurality of pixels P. According to various embodiments, the gate wire GL may include the plurality of scan lines SCL for supplying the scan signal SC and the plurality of emission control signal lines EML for supplying the emission control signal EM.

The power supply 500 may generate DC power to drive the pixel array of the display panel 100 and the display panel driver using a DC-DC converter. The DC-DC converter may include a charge pump, a regulator, a buck converter, a boost converter, and the like, but the embodiments of the present disclosure are not limited thereto.

The power supply 500 may receive a DC input voltage applied from a host system and generate DC voltages such as the gate-on voltages VGL and VEL, the gate-off voltages VGH and VEH, the high-potential driving voltage EVDD, and the low-potential driving voltage EVSS.

The gate-on voltages VGL and VEL and the gate-off voltages VGH and VEH may be supplied to a level shifter and the gate driving circuit 300. The high-potential driving voltage ELVDD and the low-potential driving voltage ELVSS may be commonly supplied to the pixels P.

The plurality of pixels P of the display panel 100 may include at least a first sub-pixel SP1, a second sub-pixel SP2, and a third sub-pixel SP3. Each of the first sub-pixel SP1, the second sub-pixel SP2, and the third sub-pixel SP3 may emit lights of different colors. For example, the first sub-pixel SP1 may be a red sub-pixel, the second sub-pixel SP2 may be a green sub-pixel, and the third sub-pixel SP3 may be a blue sub-pixel. However, the present disclosure is not limited thereto, and in some cases, the pixel PX may further include a sub-pixel SP to further implement a specific color (e.g., white).

The sizes of each of the plurality of pixels P may be the same or different. The sizes of the first sub-pixel SP1, the second sub-pixel SP2, and the third sub-pixel SP3 may be designed to be different in consideration of the lifespan of the light-emitting element (OLED) included in each of the first sub-pixel SP1, the second sub-pixel SP2, and the third sub-pixel SP3, or color balance. The sizes of the sub-pixels SP1, SP2, and SP3 may be different depending on the lifespan of the light-emitting element (OLED) of each sub-pixel SP1, SP2, and SP3. For example, since the lifespan of the red light-emitting element is longer than the lifespans of the green and blue light-emitting elements, the size of the red sub-pixel may be smaller than the sizes of the green and blue sub-pixels.

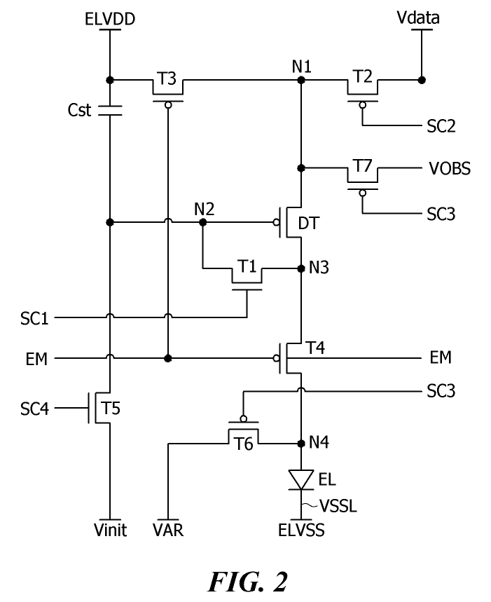

FIG. 2 is a circuit diagram of a sub-pixel included in the display apparatus according to an embodiment of the present disclosure.

Each pixel P may include a pixel driving circuit and a light-emitting part, as illustrated in FIG. 2.

The pixel driving circuit may include a first transistor T1 to a seventh transistor T7, a storage capacitor Cst, and a driving transistor DT. The light-emitting part may include a light-emitting element (OLED).

The first transistor T1 to the seventh transistor T7 and the driving transistor DT may be formed of different types of transistors. For example, one of the first transistor T1 to the seventh transistor T7 and the driving transistor DT may be a transistor having an oxide semiconductor as an active layer. Since the oxide semiconductor material has a low off-current, it may be suitable for a switching transistor having a short turn-on time and a long turn-off time. As another example, other one of the first transistor T1 to the seventh transistor T7 and the driving transistor DT may be a transistor having Low Temperature Poly-Silicon (LTPS) as an active layer. Since the poly-silicon material has high mobility, low power consumption, and excellent reliability, it may be suitable for the driving transistor DT.

The first transistor T1 to the seventh transistor T7 and the driving transistor DT may be an N-type transistor or a P-type transistor. In N-type transistors, since a carrier is an electron, electrons may flow from the source electrode to the drain electrode, and current may flow from the drain electrode to the source electrode. In the P-type transistors, since a hole as a carrier, holes may flow from the source electrode to the drain electrode, and current may flow from the source electrode to the drain electrode. For example, one of the first transistor T1 to the seventh transistor T7 and the driving transistor DT may be an N-type transistor, and other one of the first transistor T1 to the seventh transistor T7 and the driving transistor DT may be a P-type transistor.

The pixel driving circuit may include the driving transistor DT, the first transistor T1 to the seventh transistor T7, and the storage capacitor Cst.

The driving transistor DT may include a first node N1, a second node N2, and a third node N3. In the driving transistor DT, the second node N2 may be a gate node, the first node N1 may be a source node or a drain node, and the third node N3 may be a drain node or a source node. Hereinafter, for convenience of explanation, in the driving transistor DT, a case, in which the second node N2 may be a gate node, the first node N1 may be a source node, and the third node N3 may be a drain node, is taken as an example, but the embodiments of the present disclosure are not limited thereto.

A gate electrode of a driving transistor DT may be connected to the second node N2, and a first electrode of the driving transistor DT may be connected to the first node N1. A second electrode of the driving transistor DT may be connected to the third node N3. The driving transistor DT may be controlled according to a voltage of the second node N2 to control a current flowing to a light-emitting element (OLED).

A first transistor T1 may be connected between the second node N2 and the third node N3. The first transistor T1 may be controlled by a first scan signal Scan1(n) to switch between the second node N2 and the third node N3.

A second transistor T2 may be connected to the first node N1. The second transistor T2 may be controlled by a second scan signal Scan2(n) to supply the data voltage Vdata to the first node N1.

A third transistor T3 may be connected to the first node N1. The third transistor T3 may be controlled by an emission control signal EM(n) to supply the high-potential driving voltage ELVDD supplied through a high-potential driving voltage line to the first node N1.

A fourth transistor T4 may be connected between the third node N3 and a fourth node N4. The fourth transistor T4 may be controlled by the emission control signal EM(n) to switch between the third node N3 and the fourth node N4.

A fifth transistor T5 may be connected to the second node N2. The fifth transistor T5 may be controlled by a fourth scan signal Scan4(n) to supply the initialization voltage Vini to the second node N2.

A sixth transistor T6 may be connected to a fourth node N4. The sixth transistor T6 may be controlled by a third scan signal Scan3(n) to supply the anode reset voltage VAR to the fourth node N4.

A seventh transistor T7 may be connected to the first node N1. The seventh transistor T7 may be controlled by the third scan signal Scan3(n) to supply the bias voltage Vobs to the first node N1. The gate-source voltage (Vgs) flowing to the driving transistor DT may be adjusted by the bias voltage Vobs, thereby improving the hysteresis of the driving transistor DT. For example, the threshold voltage (Vth) of the driving transistor DT may be changed by applying the bias voltage Vobs.

The storage capacitor Cst may be connected between a high-potential driving voltage terminal supplying the high-potential driving voltage ELVDD and the second node N2. The storage capacitor Cst may store a data voltage Vdata. For example, the storage capacitor Cst may store the data voltage Vdata during one frame.

The light-emitting element (OLED) may include an anode and a cathode. The anode electrode of the light-emitting element (OLED) may be connected to the fourth node N4. The cathode of the light-emitting element (OLED) may be connected to a low-potential driving voltage line VSSL that supplies the low-potential driving voltage ELVSS.

The light-emitting element (OLED) may include one of an organic emission layer, an inorganic emission layer, and a quantum dot emission layer, or may include a stacked or mixed structure of an organic emission layer (or an inorganic emission layer) and a quantum dot emission layer. For example, the light-emitting element may be an organic light-emitting element including an anode, an organic layer, and a cathode. As another example, a micro LED (light-emitting diode), a quantum dot light-emitting diode (QLED) including quantum dots (QD), or the like may be further used as the light-emitting element.

The light-emitting element (OLED) may output light corresponding to any one of a variety of colors, such as red, green, and blue, or may output white light.

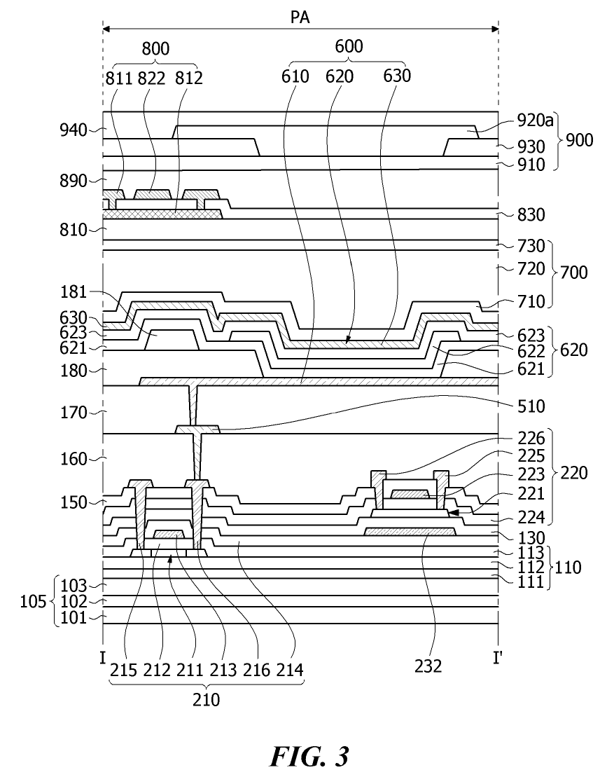

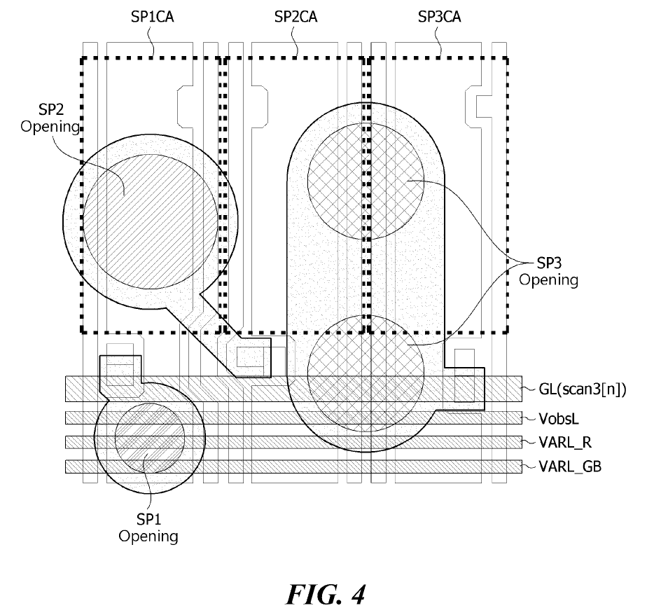

FIG. 3 is a cross-sectional view illustrating a partial area around a light-emitting element (OLED) of the display apparatus according to an embodiment of the present disclosure. FIG. 4 is a plan view illustrating a plurality of sub-pixels SP1, SP2 and SP3 included in a pixel P of FIG. 1. Referring to FIG. 3, the display apparatus 10 may include an element substrate 105, a buffer film 110, a first transistor T1, 220, a sixth transistor T6, 210, a first gate insulating film 212, an interlayer insulating film 214, a first protective film 130, a fourth insulating film 224, a second protective film 150, a first protective layer 160, a second protective layer 170, an intermediate electrode 510, a bank 180, a spacer 181, a light-emitting element 600, an encapsulating member 700, a touch part 800, a touch buffer film 810, an insulating film 890, a third buffer layer 910, an anti-reflecting layer 900, and an overcoating layer 940. Partial areas around the light-emitting element (OLED) of the display apparatus may include the first transistor T1, 220 and the sixth transistor T6, 210, but the embodiments of the present disclosure are not limited thereto.

The display apparatus 10 may include the element substrate 105. The element substrate 105 may include an insulating material. For example, the element substrate 105 may include glass or plastic, but the embodiments of the present disclosure are not limited thereto. The element substrate 105 may have a multilayer structure, but the embodiments of the present disclosure are not limited thereto. For example, the element substrate 105 may have a structure in which a first substrate layer 101, a substrate insulating layer 102, and a second substrate layer 103 are stacked. The second substrate layer 103 may include the same material as the first substrate layer 101, but the embodiments of the present disclosure are not limited thereto. For example, the first substrate layer 101 and the second substrate layer 103 may include a polymer material such as polyimide PI, but the embodiments of the present disclosure are not limited thereto. The substrate insulating layer 102 may include an insulating material. Accordingly, in the display apparatus according to the embodiment of the present disclosure, the element substrate 105 may have flexibility. Consequently, in the display apparatus according to the embodiment of the present disclosure, damage to the element substrate 105 due to bending stress may be prevented or reduced.

The element substrate 105 may include a display area, a bending area, and a pad area. The display area may include a plurality of pixel areas PA, and the light-emitting element 600 may be arranged in each pixel area PA. The light-emitting element 600 may emit light representing a specific color. For example, the light-emitting element 600 may include an anode 610, an emission layer 620, and a cathode 630 stacked on the element substrate 105.

The anode 610 may include a conductive material. The anode 610 may be formed of a material having high reflectivity. For example, the anode 610 may include a metal such as aluminum (Al) and silver (Ag), but the embodiments of the present disclosure are not limited thereto. The anode 610 may have a multilayer structure. For example, the anode 610 may have a structure in which a reflective electrode made of a metal is arranged between transparent electrodes made of a transparent conductive material such as ITO and IZO, but the embodiments of the present disclosure are not limited thereto.

The emission layer 620 may generate light with a luminance corresponding to the voltage difference between the anode 610 and the cathode 630. For example, the emission layer 620 may include an emission material layer EML and 622 including an emission material. The emission material may include an organic material, an inorganic material, or a hybrid material. For example, the display apparatus according to the embodiment of the present disclosure may be an organic light-emitting display apparatus in which the emission layer 620 includes an emission material layer 622 made of an organic material. Without being limited thereto, the emission layer 620 may include an inorganic emission material. For example, the emission layer 620 may be formed of a material including a quantum dot, a micro LED, or a mini LED, but the embodiments of the present disclosure are not limited thereto.

The emission layer 620 may have a multilayer structure. For example, the emission layer 620 may include at least one of a first common layer 621 positioned between the anode 610 and the emission material layer 622 and a second common layer 623 positioned between the emission material layer 622 and the cathode 630. The first common layer 621 and the second common layer 623 may each include at least one of a Hole Injection Layer (HIL), a Hole Transport Layer (HTL), a Hole Blocking Layer (HBL), an Electron Blocking Layer (EBL), an Electron Transport Layer (ETL), and an Electron Injection Layer (EIL), but the embodiments of the present disclosure are not limited thereto. For example, in the display apparatus according to an embodiment of the present disclosure, the first common layer 621 may include at least one of a Hole Injection Layer (HIL), an Electron Blocking Layer (EBL), and a Hole Transport Layer (HTL), and the second common layer 623 may include at least one of an Electron Transport Layer (ETL), a Hole Blocking Layer (HBL), and an Electron Injection Layer (EIL).

The cathode 630 may include a conductive material. The cathode 630 may include a different material from the anode 610, but the embodiments of the present disclosure are not limited thereto. For example, the cathode 630 may be a transparent electrode made of a transparent conductive material such as ITO and IZO. The cathode 630 may have higher transmittance than the anode 610. Accordingly, in the display apparatus according to the embodiments of the present disclosure, light generated by the emission layer 620 may be emitted through the cathode 630.

The buffer film 110 may be arranged on the element substrate 105. The buffer film 110 may prevent or reduce contamination of the element substrate 105 during the forming process of the driving circuits or may delay diffusion of moisture or oxygen that has penetrated into the element substrate 105. For example, the buffer film 110 may cover the display area AA of the element substrate 105. For example, the buffer film 110 may completely cover the display area AA of the element substrate 105. The buffer film 110 may include a multi-buffer layer and an active buffer layer 113. For example, the multi-buffer layer may have a stacked structure of a first buffer layer 111 and a second buffer layer 112 including a different material from the first buffer layer 111, but the embodiments of the present disclosure are not limited thereto. The active buffer layer 113 protects a first semiconductor layer 211 and may block various types of defects introduced from the element substrate 105. The buffer film 110 may include an insulating material. For example, the buffer film 110 may include an inorganic insulating material such as silicon oxide (SiO) and silicon nitride (SiN), but the embodiments of the present disclosure are not limited thereto.

The sixth transistor T6, 210 may be arranged on the buffer film 110. The sixth transistor T6, 210 may include the first semiconductor layer 211, the first gate insulating film 212, a first gate electrode 213, the interlayer insulating film 214, a first source electrode 215, and a first drain electrode 216. Here, depending on the design of the pixel circuit, the first source electrode 215 may become the first drain electrode 216, and the first drain electrode 216 may become the first source electrode 215. The sixth transistor T6, 210 may be electrically connected to the light-emitting element 600.

The first semiconductor layer 211 may be arranged on the buffer film 110. The first semiconductor layer 211 may include a semiconductor material. For example, the first semiconductor layer 211 may include silicon. The first semiconductor layer 211 may include a polycrystalline semiconductor. For example, the first semiconductor layer 211 may include Low Temperature Poly-Si (LTPS), but the embodiments of the present disclosure are not limited thereto. For another example, the first semiconductor layer 211 may include an oxide semiconductor. The first semiconductor layer 211 may include a first source area, a first drain area, and a first channel area.

The first gate insulating film 212 may be arranged on the first semiconductor layer 211. The first gate insulating film 212 may extend to the outside of the first semiconductor layer 211. For example, a side surface of the first semiconductor layer 211 may be covered by the first gate insulating film 212. The first gate insulating film 212 may include an insulating material. For example, the first gate insulating film 212 may include silicon oxide (SiO) and/or silicon nitride (SiN), but the embodiments of the present disclosure are not limited thereto. The silicon oxide (SiO) may include silicon dioxide (SiO2). For example, the first gate insulating film 212 may include a High-K material such as hafnium oxide (HfO), but the embodiments of the present disclosure are not limited thereto. The first gate insulating film 212 may be a gate insulating film, but is not limited thereto.

The first gate electrode 213 may be arranged on the first gate insulating film 212. The first gate electrode 213 may include a conductive material. For example, the first gate electrode 213 may include a single layer or multiple layers including aluminum (Al), chromium (Cr), copper (Cu), titanium (Ti), molybdenum (Mo), and tungsten (W) or alloys thereof, but the embodiments of the present disclosure are not limited thereto.

The interlayer insulating film 214 may be arranged on the first gate electrode 213. The interlayer insulating film 214 may extend to the outside of the first gate electrode 213. For example, a side surface of the first gate electrode 213 may be covered by the second interlayer insulating film 214. The interlayer insulating film 214 may extend along the first gate insulating film 212. The interlayer insulating film 214 may include an insulating material. For example, the interlayer insulating film 214 may include silicon oxide (SiO), but the embodiments of the present disclosure are not limited thereto.

The first protective film 130 may be arranged on the interlayer insulating film 214. The first protective film 130 may be formed of a single layer or multiple layers of silicon nitride (SiNx) or silicon oxide (SiOx). The first protective film 130 may prevent or reduce damage to the sixth transistor T6, 210 due to external impact and moisture. The first protective film 130 may extend between an auxiliary layer 232 of each pixel area PA and a second semiconductor layer 221. Accordingly, in the display apparatus according to the embodiment of the present disclosure, damage to the sixth transistor T6, 210 due to external impact and moisture may be effectively prevented or reduced.

The second semiconductor layer 221 of the first transistor T1, 220 may be arranged on the first protective film 130. For example, the first transistor T1, 220 may include the second semiconductor layer 221, the fourth insulating film 224, a second gate electrode 223, a second source electrode 225, and a second drain electrode 226.

The second semiconductor layer 221 may be formed of an oxide semiconductor. Since the oxide semiconductor material has a larger band gap than the silicon material, electrons cannot cross the band gap in the off state, and thus the off-current is low. Therefore, a thin film transistor including an active layer formed of an oxide semiconductor may be suitable for a switching thin film transistor having a short on-time and a long off-time, but is not limited thereto. In addition, since the off-current is small, the size of the auxiliary capacitance may be reduced, and thus the thin film transistor is suitable for a high-resolution display element. For example, the second semiconductor layer 221 of the first transistor T1, 220 may be formed of a metal oxide, and may be formed of various metal oxides, such as indium-gallium-zinc-oxide (IGZO). Here, it is explained assuming that the second semiconductor layer 221 is formed of IGZO among various metal oxides, but it is not limited thereto and may be formed of other metal oxides such as IZO (indium-zinc-oxide), IGTO (indium-gallium-tin-oxide), or IGO (indium-gallium-oxide) other than IGZO.

The second semiconductor layer 221 may be formed by depositing a metal oxide on the first protective film 130, performing a heat treatment process for stabilization, and then patterning the metal oxide.

For another example, the second semiconductor layer 221 may include Low Temperature Poly-Si (LTPS).

The second semiconductor layer 221 may be arranged on a different layer from the first semiconductor layer 211. For example, the first protective film 130 may be positioned on the interlayer insulating film 214, and the second semiconductor layer 221 may be arranged on the first protective film 130. The first protective film 130 may include silicon oxide (SiOx) or silicon nitride (SiNx), but the embodiments of the present disclosure are not limited thereto. Accordingly, in the display apparatus according to the embodiment of the present disclosure, damage to the second semiconductor layer 221 due to the formation process of the first semiconductor layer 211 may be prevented or reduced.

The second semiconductor layer 221 may include a second source area, a second drain area, and a second channel area. The second channel area may be arranged between the second source area and the second drain area. The second source area and the second drain area may have lower resistance than the second channel area. For example, the second source area and the second drain area may include a conductive area of an oxide semiconductor. The second channel area may be a non-conductive area of an oxide semiconductor.

The fourth insulating film 224 may be arranged on the second semiconductor layer 221. The fourth insulating film 224 may include an insulating material. The fourth insulating film 224 may include the same material as the first gate insulating film 212, but the embodiments of the present disclosure are not limited thereto. For example, the fourth insulating film 224 may have a multilayer structure, but the embodiments of the present disclosure are not limited thereto. The fourth insulating film 224 may be a gate insulating film, but is not limited thereto.

The second gate electrode 223 may be arranged on the fourth insulating film 224. For example, the second gate electrode 223 may overlap the second channel area of the second semiconductor layer 221. The second gate electrode 223 may include a conductive material. For example, the second gate electrode 223 may include a single layer or multiple layers including aluminum (Al), chromium (Cr), copper (Cu), titanium (Ti), molybdenum (Mo), and tungsten (W) or alloys thereof, but the embodiments of the present disclosure are not limited thereto. The second gate electrode 223 may include the same material as the first gate electrode 213, but the embodiments of the present disclosure are not limited thereto. The second gate electrode 223 may be insulated from the second semiconductor layer 221 by the fourth insulating film 224. For example, the second channel area of the second semiconductor layer 221 may have an electrical conductivity corresponding to the voltage applied to the second gate electrode 223.

The second protective film 150 may be placed on the fourth insulating film 224. The second protective film 150 may include silicon oxide (SiOx) or silicon nitride (SiNx), but the embodiments of the present disclosure are not limited thereto.

The second source electrode 225 and the second drain electrode 226 may be arranged on the second protective film 150. The second source electrode 225 and the second drain electrode 226 may include a conductive material. For example, each of the second source electrode 225 and the second drain electrode 226 may include aluminum (Al), chromium (Cr), copper (Cu), titanium (Ti), molybdenum (Mo), and tungsten (W) or an alloy thereof, but the embodiments of the present disclosure are not limited thereto. The second source electrode 225 may include the same material as the first source electrode 215, or the second drain electrode 226 may include the same material as the first drain electrode 216, but the embodiments of the present disclosure are not limited thereto. The second source electrode 225 and the second drain electrode 226 may be insulated from the second gate electrode 223 by the fourth insulating film 224. The second source electrode 225 or the second drain electrode 226 may include a different material from the second gate electrode 223. The second source electrode 225 may be electrically connected to the second source area of the second semiconductor layer 221. For example, the fourth insulating film 224 and the second protective film 150 may include a second source contact hole that partially exposes the second source area of the second semiconductor layer 221. The second source electrode 225 may include an area overlapping the second source area of the second semiconductor layer 221. For example, the second source electrode 225 may be in contact with the second source area of the second semiconductor layer 221 within the second source contact hole. For example, the second drain electrode 226 may include the same material as the second source electrode 225, but the embodiments of the present disclosure are not limited thereto. The second drain electrode 226 may be formed by the same process as the second source electrode 225. The second drain electrode 226 may be electrically connected to the second drain area of the second semiconductor layer 221. The second drain electrode 226 may be spaced apart from the second source electrode 225. For example, the fourth insulating film 224 and the second protective film 150 may include a second drain contact hole that partially exposes the second drain area of the second semiconductor layer 221. The second drain electrode 226 may include an area overlapping with the second drain area of the second semiconductor layer 221. For example, the second drain electrode 226 may contact the second drain area of the second semiconductor layer 221 within the second drain contact hole.

The first transistor T1, 220 may further include the auxiliary layer 232 below the second semiconductor layer 221. The auxiliary layer 232 may overlap the second semiconductor layer 221. For example, the auxiliary layer 232 may include a single layer or multiple layers including aluminum (Al), chromium (Cr), copper (Cu), titanium (Ti), molybdenum (Mo), nickel (Ni), neodymium (Nd), and tungsten (W) or an alloy thereof, but the embodiments of the present disclosure are not limited thereto. Since the auxiliary layer 232 may prevent or reduce light directed to the second semiconductor layer 221, the lifespan of the second thin film transistor 220 may be extended. For example, the auxiliary layer 232 may be a light-shielding layer, but is not limited thereto. For example, an auxiliary layer may be formed below the sixth transistor T6, 210. The auxiliary layer may be arranged on the buffer layer 112. When the auxiliary layer is formed, an insulating film may be further formed on the buffer layer 112. The auxiliary layer may be formed of the same material as the auxiliary layer 232, but the embodiments of the present disclosure are not limited thereto. Since the auxiliary layer may prevent or reduce light directed to the first semiconductor layer 211, the lifespan of the sixth transistor T6, 210 may be extended.

The second protective film 150 may be arranged between the fourth insulating film 224 and the second source electrode 225 of each pixel area PA and between the fourth insulating film 224 and the second drain electrode 226. The second protective film 150 may prevent or reduce damage to the second semiconductor layer 221 due to external impact and moisture. For example, the second protective film 150 may extend to the outside of the second semiconductor layer 221 along the fourth insulating film 224. The second protective film 150 may include a different material from the fourth insulating film 224. For example, the second protective film 150 may include silicon nitride (SiN), but the embodiments of the present disclosure are not limited thereto. Accordingly, in the display apparatus according to the embodiment of the present disclosure, damage to the second semiconductor layer 221 due to external impact and moisture may be effectively prevented or reduced.

The first source electrode 215 and the first drain electrode 216 of the sixth transistor T6, 210 may be arranged on the second protective film 150 of each pixel area PA. The first source electrode 215 and the first drain electrode 216 may include a conductive material. For example, each of the first source electrode 215 and the first drain electrode 216 may include a single layer or multiple layers including aluminum (Al), chromium (Cr), copper (Cu), titanium (Ti), molybdenum (Mo), and tungsten (W) or an alloy thereof, but the embodiments of the present disclosure are not limited thereto. The first source electrode 215 and the first drain electrode 216 may include a different material from the first gate electrode 213, but the embodiments of the present disclosure are not limited thereto. The first source electrode 215 may be electrically connected to the first source area of the first semiconductor layer 211. For example, the first insulating film 212, the interlayer insulating film 214, the first protective film 130, the fourth insulating film 224, and the second protective film 150 may include a first contact hole that partially exposes the first source area of the first semiconductor layer 211 of the sixth transistor T6 and 210. The first source electrode 215 may include an area overlapping the first source area of the first semiconductor layer 211. For example, the first source electrode 215 may contact the first source area of the first semiconductor layer 211 within the first source contact hole. For example, the first drain electrode 216 may include the same material as the first source electrode 215, but the embodiments of the present disclosure are not limited thereto. The first drain electrode 216 may be formed by the same process as the first source electrode 215. The first drain electrode 216 may be electrically connected to the first drain area of the first semiconductor layer 211. The first drain electrode 216 may be spaced apart from the first source electrode 215. For example, the first insulating film 212, the interlayer insulating film 214, the first protective film 130, the fourth insulating film 224, and the second protective film 150 may include a first contact hole that partially exposes the first drain area of the first semiconductor layer 211. The first drain electrode 216 may include an area overlapping with the first drain area of the first semiconductor layer 211. For example, the first drain electrode 216 may contact the first drain area of the first semiconductor layer 211 within the first contact hole.

The light-emitting element 600 of each pixel area PA may be arranged on the transistor of the corresponding pixel area PA. For example, the sixth transistor T6, 210 and the first transistor T1, 220 of each pixel area PA may be arranged between the element substrate 105 and the anode 610 of the corresponding pixel area PA. Therefore, in the display apparatus according to the embodiment of the present disclosure, the area occupied by each pixel area PA may be minimized or reduced. Accordingly, in the display apparatus according to the embodiment of the present disclosure, the resolution may be improved.

The first protective layer 160 and the second protective layer 170 may be arranged between the driving circuit and the light-emitting element 600 of each pixel area PA. For example, the anode 610, the emission layer 620, and the cathode 630 of each pixel area PA may be arranged on the second protective layer 170 of the corresponding pixel area PA. The first protective layer 160 and the second protective layer 170 may reduce or eliminate a step caused by the transistor. For example, the upper surface of the second protective layer 170 facing the light-emitting element 600 of each pixel area PA may be a flat surface. The first protective layer 160 and the second protective layer 170 may include an insulating material. For example, the first protective layer 160 and the second protective layer 170 may include an organic insulating material. The second protective layer 170 may include a different material from the first protective layer 160. In addition, in order to form a flatter upper surface on which the cathode 630 is placed, additional layers may be arranged on the second protective layer 170, and the additional layers may include an insulating material and may include an organic insulating material. Accordingly, in the display apparatus according to the embodiment of the present disclosure, the step caused by the transistors may be effectively reduced or eliminated.

The intermediate electrode 510 may be arranged between the first protective layer 160 and the second protective layer 170 of each pixel area PA. The light-emitting element 600 may be electrically connected to the first drain electrode 216 of the sixth transistor T6, 210 through the intermediate electrode 510. For example, the intermediate electrode 510 may penetrate the first protective layer 160 and be connected to the first drain electrode 216, and the anode 610 of the light-emitting element 600 may penetrate the second protective layer 170 and be connected to the intermediate electrode 510. The intermediate electrode 510 may include an area overlapping the first drain electrode 216 and an area overlapping the anode 610. For example, the intermediate electrode 510 may be arranged between the first drain electrode 216 and the anode 610. The intermediate electrode 510 may be in contact with the first drain electrode 216. For example, the intermediate electrode 510 may be in direct contact with the first drain electrode 216. The anode 610 may be in contact with the intermediate electrode 510. For example, the anode 610 may be in direct contact with the intermediate electrode 510. The intermediate electrode 510 may include a conductive material. For example, the intermediate electrode 510 may include a metal such as aluminum (Al), chromium (Cr), copper (Cu), titanium (Ti), molybdenum (Mo), and tungsten (W). The intermediate electrode 510 may include a different material from the first drain electrode 216 and the anode 610, but the embodiments of the present disclosure are not limited thereto.

The bank 180 may be arranged on the second protective layer 170 of each pixel area PA. The bank 180 may have a single-layer structure, but the embodiments of the present disclosure are not limited thereto. The bank 180 may include an insulating material. For example, the bank 180 may be formed of a material including a black pigment or the like, or an organic material such as a benzocyclobutene resin, a polyimide resin, an acrylic resin, or a photosensitive polymer, but the embodiments of the present disclosure are not limited thereto. When the bank 180 is formed of a material including a black pigment, a black dye or the like, it may be a black bank. When the bank 180 is formed of a material including a black pigment or a black dye, light from the outside may be blocked, and the luminance of the display apparatus may be further improved. In another embodiment, the bank 180 may have a multi-layer structure, but the embodiments of the present disclosure are not limited thereto. For example, the bank 180 may have a structure in which a first bank layer and a second bank layer are stacked. The first bank layer may be formed of a material that may form the bank 180 of the single-layer structure, but the embodiments of the present disclosure are not limited thereto. A second bank layer may be formed of a material including a transparent pigment or a transparent dye, or the like. For example, the second bank layer may be formed of a polyimide resin, an acrylic resin, or an organic material having high light transmittance, but the embodiments of the present disclosure are not limited thereto. The bank 180 may cover an edge of the anode 610. The emission layer 620 and the cathode 630 of each pixel area PA may be arranged on a portion of the anode 610 exposed by the bank 180. For example, the bank 180 may define an emission area within each pixel area PA.

A spacer 181 may be arranged on the bank 180 of each pixel area PA. The spacer 181 may be formed with a width narrower than the width of the bank 180. The spacer 181 may include an insulating material. For example, the spacer 181 may include an organic insulating material. The spacer 181 may be formed of the same material as the bank 180, but the embodiments of the present disclosure are not limited thereto. The spacer 181 may prevent or reduce damage to the emission material layer 622 formed on the bank 180 and an adjacent pixel area PA by the fine metal mask.

The emission layer 620 of each pixel area PA may extend over the bank 180 and the spacer 181. Each pixel area PA may exhibit a different color from the adjacent pixel area PA. For example, the emission material layer 622 of each pixel area PA may be separated from the emission material layer 622 of the adjacent pixel area PA. The emission material layer 622 of each pixel area PA may include an end positioned within the corresponding pixel area PA. The emission material layer 622 may be formed using a fine metal mask FMM. The end of each emission material layer 622 may be arranged over the bank 180. The first common layer 621 and the second common layer 623 of each emission layer 620 may extend along the surface of the bank 180. For example, the first common layer 621 and the second common layer 623 of each pixel area PA may be connected to the first common layer 621 and the second common layer 623 of the adjacent pixel area PA. Accordingly, the process efficiency may be improved in the display apparatus according to the embodiment of the present disclosure.

The voltage supplied to the cathode 630 of each pixel area PA may be the same as the voltage supplied to the cathode 630 of the adjacent pixel area PA. For example, the cathode 630 of each pixel area PA may be connected to the cathode 630 of the pixel area PA adjacent to the bank 180. Accordingly, the display apparatus according to the embodiment of the present disclosure may control the luminance of the corresponding pixel area PA through the gate signal and data signal applied to each pixel area PA. The cathode 630 of each pixel area PA may be in contact with the cathode 630 of the adjacent pixel area PA.

An encapsulating member 700 may be arranged on the light-emitting element 600 of each pixel area PA. The encapsulating member 700 may prevent or reduce damage to the light-emitting elements 600 due to external impact and moisture. The encapsulating member 700 may have a multilayer structure, but the embodiments of the present disclosure are not limited thereto. For example, the encapsulating member 700 may include a first encapsulating layer 710, a second encapsulating layer 720, and a third encapsulating layer 730, but the embodiments of the present disclosure are not limited thereto. The first encapsulating layer 710, the second encapsulating layer 720, and the third encapsulating layer 730 may include an insulating material. The second encapsulating layer 720 may include a different material from the first encapsulating layer 710 and the third encapsulating layer 730, but the embodiments of the present disclosure are not limited thereto. For example, the first encapsulating layer 710 and the third encapsulating layer 730 may include an inorganic insulating material, and the second encapsulating layer 720 may include an organic insulating material. Accordingly, in the display apparatus according to the embodiment of the present disclosure, damage to the light-emitting elements 600 due to external impact and moisture may be effectively prevented or reduced. The step caused by the light-emitting elements 600 of each pixel area PA may be removed by the encapsulation member 700. For example, the upper surface of the encapsulation member 700 facing the element substrate 105 may be a flat plane.

The touch part 800 may be arranged on the encapsulation member 700. The touch part 800 may sense a touch of a user and/or a tool. For example, the touch part 800 may include touch electrodes 811 and 822 and bridge electrodes 812. The touch electrodes 811 and 822 may be arranged in parallel. The bridge electrodes 812 may connect between separated touch electrodes 811. The touch electrodes 811 and 822 and bridge electrodes 812 may include a conductive material. For example, the touch electrodes 811 and 822 and bridge electrodes 812 may include a single layer or double layer including aluminum (Al), chromium (Cr), copper (Cu), titanium (Ti), molybdenum (Mo), and tungsten (W) or an alloy thereof, but the embodiments of the present disclosure are not limited thereto. The touch electrodes 811 and 822 and bridge electrodes 812 may overlap the display area of the element substrate 105. The light-emitting element 600 of each pixel area PA may be arranged on the outer side of the touch electrodes 811 and 822 and bridge electrodes 812. For example, the touch electrodes 811 and 822 and bridge electrodes 812 may overlap the bank 180. The touch electrodes 811 and 822 and bridge electrodes 812 may be spaced apart from the light-emitting elements 600 of each pixel area PA. Therefore, in the display apparatus according to the embodiment of the present disclosure, light emitted in a direction perpendicular to the upper surface of the element substrate 105 from each light-emitting element 600 may not be blocked by the touch electrodes 811 and 822 and bridge electrodes 812. Accordingly, in the display apparatus according to the embodiment of the present disclosure, a decrease in the luminance of each pixel area PA due to the touch electrodes 811 and 822 and bridge electrodes 812 may be prevented.

A touch insulating film 830 may be arranged between each bridge electrodes 812 and the touch electrodes 811 and 822. The touch insulating film 830 may include an insulating material. For example, the touch insulating film 830 may include a material such as silicon oxide (SiOx) and silicon nitride (SiNx), but the embodiments of the present disclosure are not limited thereto. The second touch electrodes 822 may be arranged on the same layer as the first touch electrodes 811. For example, the touch electrodes 811 and 822 may be arranged on the touch insulating film 830 covering the bridge electrodes 812. The touch insulating film 830 may include touch contact holes that partially expose the bridge electrodes 812. The touch electrodes 811 may be connected to the corresponding bridge electrode 812 through one of the touch contact holes.

The touch buffer film 810 may be arranged between the encapsulation member 700 and the touch part 800. The touch buffer film 810 may prevent or reduce damage to the encapsulation member 700 and the light-emitting elements 600 due to the forming process of the touch electrodes 811 and 821 and the bridge electrodes 812. The touch buffer film 810 may include an insulating material. For example, the touch buffer film 810 may include a material such as silicon oxide (SiOx) and silicon nitride (SiNx), but the embodiments of the present disclosure are not limited thereto.

The insulating film 890 may be arranged on the touch part 800. The insulating film 890 may prevent or reduce damage to the touch part 800 due to external impact and moisture.

The anti-reflecting layer 900 may be arranged on the touch part 800. The anti-reflecting layer 900 may include a plurality of color filters 920a and a black matrix 930. The plurality of color filters 920a and a black matrix 930 of the anti-reflecting layer 900 may have the function of absorbing external light to minimize or reduce the deterioration of the visibility and contrast ratio of the display panel 100 caused by external light.

The black matrix 930 may be arranged over the touch part 800 or the third buffer layer 910. In this case, the third buffer layer 910 prevents or reduces the penetration of moisture or oxygen from the outside and protects the components of the display panel 100. The third buffer layer 910 may be formed of an inorganic material having excellent barrier properties. Accordingly, the penetration of moisture or oxygen may be minimized or reduced. For example, the third buffer layer 910 may be formed of one or more inorganic materials selected from silicon nitride (SiNx), silicon oxide (SiOx), silicon oxynitride (SiON), or aluminum oxide (Al2O3), but is not limited thereto. In addition, the third buffer layer 910 may supplement the decrease in adhesion between the plurality of color filters 920a and the black matrix 930 and the insulating film 890. The third buffer layer 910 may be omitted when the touch part 800 is arranged on the upper portion of the encapsulation member 700 or on the lower portion of the encapsulation member 700 through an adhesive member.

The black matrix 930 is arranged along the boundaries of the sub-pixels SP1, SP2 and SP3 and includes an opening that exposes the sub-pixels SP1, SP2 and SP3. The black matrix 930 divides each of the plurality of color filters 920a. The black matrix 930 may be arranged to overlap the bank 180. Accordingly, color mixing between the sub-pixels SP1, SP2 and SP3 may be minimized or reduced. In addition, the black matrix 930 may absorb external light. Accordingly, the deterioration of the visibility and contrast ratio of the display panel 100 due to external light may be minimized or reduced.

In this case, the size of the opening may be different for each sub-pixel SP1, SP2 and SP3. For example, the size of the opening defined by the black matrix 930 may correspond to the size of the opening defined by the bank 180. That is, the size of the opening of the black matrix of the sub-pixel SP1, SP2 and SP3 and the size of the opening of the bank may be different depending on the lifespan of the light-emitting element 600 of the sub-pixel SP1, SP2 and SP3. For example, the size of the opening of the black matrix of the red sub-pixel and the size of the opening of the bank may be smaller than the size of the opening of the black matrix of the green and blue sub-pixels and the size of the opening of the bank.

The black matrix 930 may be formed of an organic material. The black matrix 930 includes a base resin and a black material. The base resin may be at least one selected from a cardo-based resin, an epoxy-based resin, an acrylate-based resin, a siloxane-based resin, and a polyimide, but is not limited thereto. The black material may be a black pigment selected from a carbon-based pigment, a metal oxide-based pigment, and an organic pigment. For example, the carbon-based pigment may be carbon black. For example, the metal oxide-based pigment may include titanium black (TiNxOy), Cu-Mn-Fe-based black pigment, or the like, but is not limited thereto. For example, the organic pigment may be selected from lactam black, perylene black, and aniline black, but is not limited thereto. Additionally, RGB black pigment including red pigment, blue pigment, and green pigment may be used as black material.

A plurality of color filters 920a may be arranged over the touch part 800 or the third buffer layer 910. In addition, the plurality of color filters 920a may be arranged to be in direct contact with the third buffer layer 910 and may be arranged to cover a portion of the black matrix 930. The plurality of color filters 920a absorb external light to minimize or reduce the deterioration of the visibility and contrast ratio due to external light, and improve color reproducibility. By arranging the plurality of color filters 920a over the encapsulation member 700, the emission efficiency may be improved and a conventional polarizing plate may be omitted.

A plurality of color filters 920a are arranged to correspond to a plurality of sub-pixels SP1, SP2 and SP3 arranged below. For example, the plurality of color filters 920a include a first color filter corresponding to a first sub-pixel SP1, a second color filter corresponding to a second sub-pixel SP2, and a third color filter corresponding to a third sub-pixel SP3. In this case, the first color filter, the second color filter, and the third color filter may correspond to the colors of the corresponding sub-pixels. For example, when the first sub-pixel SP1 is a red sub-pixel, the first color filter is a red color filter, and the first color filter transmits red light. When the second sub-pixel SP2 is a green sub-pixel, the second color filter is a green color filter, and the second color filter transmits green light. When the third sub-pixel SP3 is a blue sub-pixel, the third color filter is a blue color filter, and the third color filter transmits blue light.

Each color filter 920a includes a transparent base resin and a coloring material. For example, the transparent base resin may be one selected from polyacrylate, polymethyl methacrylate, polyimide, polyvinyl alcohol, polyethylene, polypropylene, polystyrene, polyethylene terephthalate, and the like, but is not limited thereto.

The overcoating layer 940 may be arranged over a plurality of color filters 920a and a black matrix 930. The overcoating layer 940 may planarize the upper portions of the plurality of color filters 920a and the black matrix 930. The overcoating layer 940 may be formed of a transparent resin such as an acrylic resin, a silicone resin, a polyester resin, or an epoxy resin, but is not limited thereto.

The overcoating layer 940 may include a UV absorption layer. The UV absorption layer blocks light of an ultraviolet wavelength from external light incident on the display panel 100. The UV absorption layer blocks light of a wavelength of about 400 nm or less and transmits visible light of a wavelength exceeding about 400 nm. The UV absorption layer may be formed of an organic material including a UV blocking agent or UV absorber that blocks or absorbs light of a wavelength of 400 nm or less. The UV blocking agent or UV absorber may be used without limitation as long as it is a material used in the relevant technical field.

As illustrated in FIG. 4, each of the plurality of sub-pixels SP1, SP2 and SP3 included in the pixel P of the display panel 100 has a different size of an opening for each of the first to third sub-pixels SP1, SP2 and SP3. This allows the emission areas to be implemented differently based on the difference in the lifespans of the light-emitting elements 600. The lifespans of the light-emitting elements 600 are different from each other due to the materials forming the emission layer 620. The sizes of the openings defined by the black matrix 930 and the openings defined by the banks 180 are different for each of the first to third sub-pixels SP1, SP2 and SP3. Since the first to third color filters are arranged in their respective opening defined by the black matrix 930, they have different sizes for each of the first to third sub-pixels SP1, SP2 and SP3. In addition, since the first to third sub-pixels SP1, SP2 and SP3 have different opening areas, the electrode sizes of the anodes 610 are different for the first to third sub-pixels SP1, SP2 and SP3, and thus a difference in the capacitor capacitance of the light-emitting element (OLED) may occur. As a result, in low gray-scale images, the sub-pixel with the smallest capacitor capacitance of the light-emitting element (OLED) among the plurality of sub-pixels SP1, SP2 and SP3 emits light first. For example, among the red sub-pixel, the green sub-pixel, and the blue sub-pixel, the red sub-pixel with the smallest opening area emits light earlier than the sub-pixels of the other two colors. Therefore, a problem may occur in which the screen appears red in low gray-scale images.

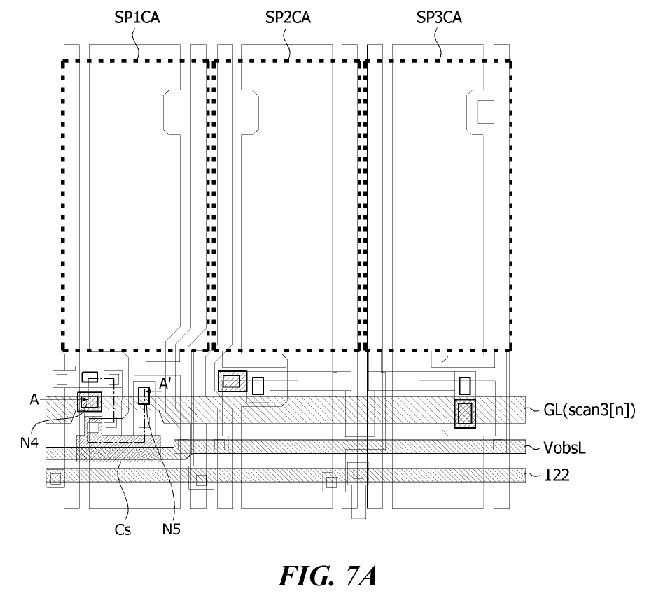

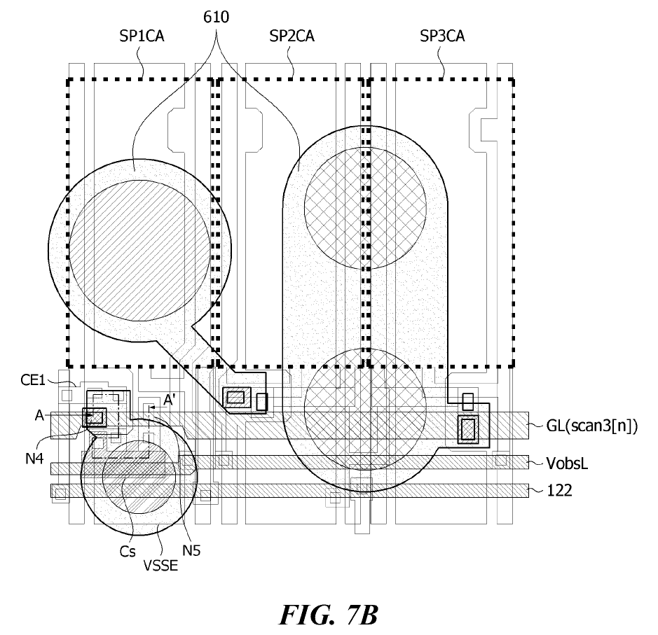

Referring to FIG. 4, in order to improve the low gray-scale image quality of the display panel 100, the anode reset voltage may be separately supplied to each of the red sub-pixel, the green sub-pixel and the blue sub-pixel, so that the anode may be reset with an optimal voltage for each sub-pixel, thereby improving the electro-optical characteristics. For example, since there is a large difference in the opening area between the red sub-pixel and the green and blue sub-pixels, it is possible to supply the anode reset voltage separately to the green and blue sub-pixels compared to the red sub-pixel. Accordingly, in the case of FIG. 4, a reset voltage line VARL_GB that commonly supplies the anode reset voltage to the green sub-pixel and the blue sub-pixel, and a reset voltage line VARL_R that supplies the anode reset voltage to the red sub-pixel may be arranged in the display panel 100. In addition, for example, a reset voltage line may be arranged for each sub-pixel in order to supply the anode reset voltage to each of the red sub-pixel, the green sub-pixel, and the blue sub-pixel, respectively. In the case of FIGS. 7A and 7B, some configurations that are not directly related to the features of the present disclosure are omitted in some circuit areas SP1CA, SP2CA and SP3CA of the pixel driving circuits of the plurality of sub-pixels SP1, SP2 and SP3.

However, in order to supply anode reset voltages of different voltage levels to the red sub-pixel, the green sub-pixel, and the blue sub-pixel of the display panel 100, a plurality of reset voltage lines may be arranged for each pixel row. In this case, it is difficult to secure the aperture ratio of pixels within the display area due to the large number of reset voltage lines, and the RC delay increases due to the resistance of other signal lines and reset voltage lines and the parasitic capacitance between the wires, making panel design difficult. In addition, due to the RC delay, the amount of charge of pixels becomes uneven depending on the location of the display panel, which may cause uneven luminance and color reproduction, resulting in deterioration. Further, if wires are added to the non-display area NA or the bezel area at the edge of the display panel in order to apply the anode reset voltage to the anode reset voltage lines, it is difficult to implement a narrow bezel, and the problem may occur that the number of channels in which the anode reset voltage is output from the power supply increases.

Therefore, the display panel 100 according to one embodiment of the present disclosure may supply a common anode reset voltage VAR to the red sub-pixel, the green sub-pixel, and the blue sub-pixel through a single common reset voltage line 120. For example, since a red sub-pixel having a small opening area of the emission part has a small capacitor capacitance, when the common anode reset voltage VAR is supplied, the red sub-pixel may reach the light-emitting element (OLED) turn-on voltage earlier than the sub-pixels of other colors, which may cause a problem with low gray-scale image quality. Therefore, by arranging an auxiliary capacitor Cs between the anode and the low-potential driving voltage line VSSL, the capacitor may be connected in parallel with the light-emitting element (OLED) to increase the capacitor capacitance so as to be similar to the capacitor capacitance of the sub-pixels of other colors, so that the times at which all the sub-pixels reach the light-emitting element (OLED) turn-on voltage may be similar. Accordingly, the display panel 100 according to one embodiment of the present disclosure may improve low gray-scale image quality without adding a separate voltage line within a display area.

The capacitor may exist between the anode electrode and the cathode electrode due to the stacked structure of the light-emitting element (OLED). The auxiliary capacitor Cs may be formed in the circuit layer of the display panel and may be additionally connected between the anode electrode and the cathode electrode of the light-emitting element (OLED) to be connected to the light-emitting element (OLED) having a relatively small capacitance, thereby increasing the capacitor capacitance of the light-emitting element (OLED).

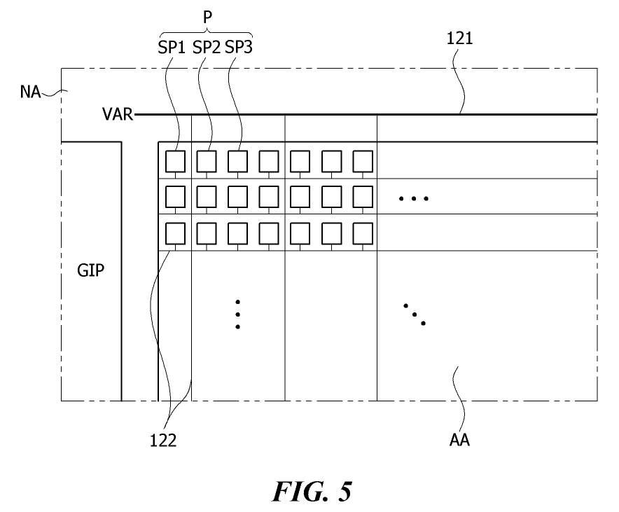

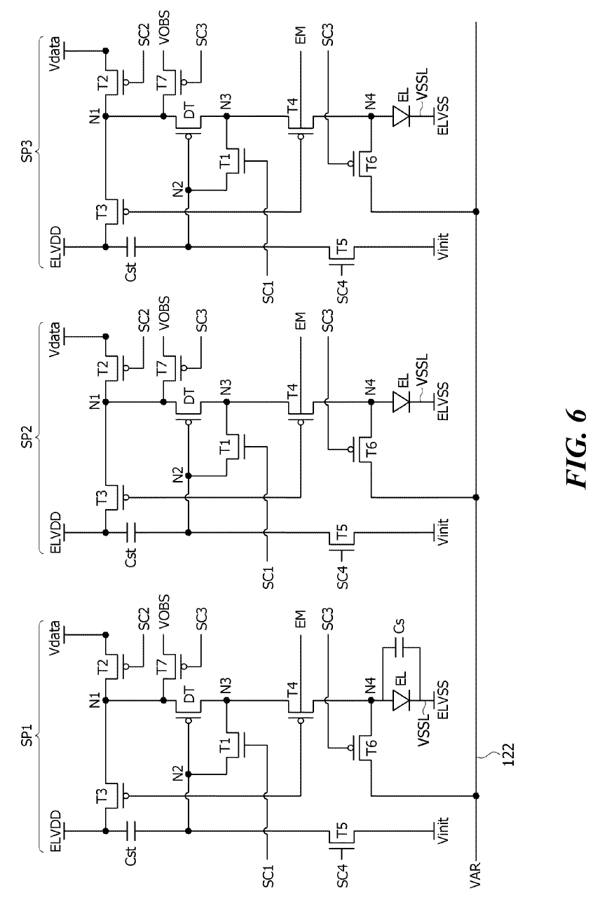

FIG. 5 is a layout view illustrating a common reset voltage line of the display apparatus according to an embodiment of the present disclosure. FIG. 6 is a layout view illustrating a circuit configuration of a plurality of sub-pixels SP1, SP2 and SP3 and a common reset voltage line, in the display apparatus according to an embodiment of the present disclosure.

The common reset voltage line 121 and 122 may be connected to the power supply 500 to supply the same anode reset voltage VAR to each of the plurality of sub-pixels SP1, SP2 and SP3. The common reset voltage line 121 and 122 may include at least one first common reset voltage line 121 and a plurality of second common reset voltage lines 122.

The first common reset voltage line 121 may be arranged in the non-display area NA of the display panel 100. The first common reset voltage line 121 may be arranged on at least one of sides of the display panel 100. For example, the first common reset voltage line 121 may be arranged to extend in the first direction in the non-display area NA in upper portion of the display panel 100.

The first common reset voltage line 121 is connected to the power supply 500, and the plurality of second common reset voltage lines 122 are connected to the first common reset voltage line 121 to supply a common anode reset voltage VAR to each of the plurality of sub-pixels SP1, SP2 and SP3.

The plurality of second common reset voltage lines 122 connected to the first common reset voltage line 121 may extend to the display area AA and be connected to the plurality of sub-pixels SP1, SP2 and SP3. The plurality of second common reset voltage lines 122 may be arranged in the first direction and a second direction different from the first direction to form a mesh. However, it is not limited to this, and may be arranged in one of the first direction or the second direction depending on the design.

A common anode reset voltage VAR may be supplied to each of the sub-pixels SP1, SP2 and SP3 arranged in an area where the second common reset voltage line 122 intersects, through a second common reset voltage line 122 arranged in the pixel row direction, according to a scan signal supplied to each of the sub-pixels SP1, SP2 and SP3. In the display apparatus according to one embodiment of the present disclosure, a common reset voltage line 121 and 122 may be connected to the plurality of pixels P to improve the voltage deviation of the fourth node N4 and to improve leakage current and color variation during the emission of the light-emitting element OLED.

As illustrated in FIGS. 5 and 6, a second common reset voltage line 122 may be arranged in each pixel row. Each of the sub-pixels SP1, SP2 and SP3 arranged in the corresponding pixel row may be connected to the second common reset voltage line 122. In FIG. 6, the pixel driving circuit of the first sub-pixel SP1 among the plurality of sub-pixels SP1, SP2 and SP3 is identical to the pixel driving circuit of the sub-pixel of FIG. 2 except for the auxiliary capacitor Cs, and therefore a detailed description thereof will be omitted. The pixel driving circuits of the second sub-pixel SP2 and the third sub-pixel SP3 are identical to the pixel driving circuit of the sub-pixel of FIG. 2, and therefore a detailed description thereof will be omitted.

Referring to FIGS. 6 to 7B, the auxiliary capacitor Cs of the pixel driving circuit of the first sub-pixel SP1 may compensate for the voltage applied to the fourth node N4. The auxiliary capacitor Cs may be connected between the fourth node N4 and a fifth node N5. The fifth node N5 may be a node connected to the low-potential driving voltage line VSSL. For example, one electrode of the auxiliary capacitor Cs may be connected to the fourth node N4, and thus may be connected to the source electrode of the fourth transistor T4, the drain electrode of the sixth transistor T6, and the anode of the light-emitting element (OLED). The other electrode of the auxiliary capacitor Cs may be connected to the fifth node N5 and thus may be connected to the low-potential driving voltage line VSSL that supplies the low-potential driving voltage ELVSS. That is, the auxiliary capacitor Cs may be connected between the fourth node N4 and the fifth node N5 to increase the overall capacitor capacitance of the light-emitting element (OLED). The auxiliary capacitor Cs may be connected to the first sub-pixel SP1 having the smallest opening area of the emission part among the plurality of sub-pixels SP1, SP2 and SP3, thereby solving the problem of the first sub-pixel SP1 being turned on first in a low gray-scale image even when a common anode reset voltage VAR is supplied.

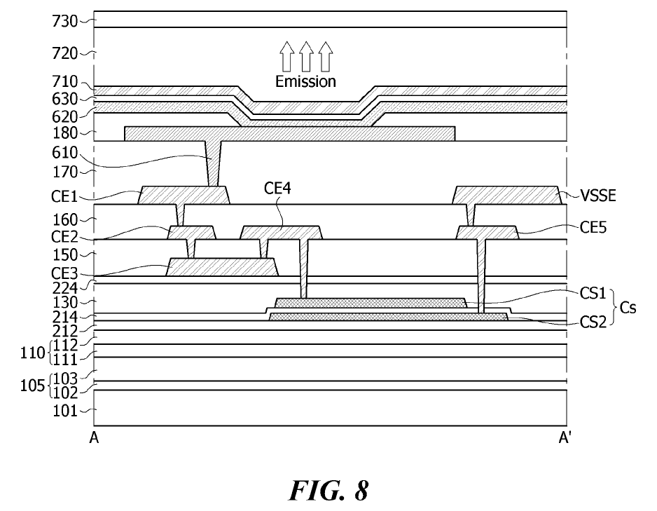

FIGS. 7A and 7B are plan views of the plurality of sub-pixels SP1, SP2 and SP3 arranged in a pixel row in the display apparatus according to one embodiment of the present disclosure. FIG. 7A is a plan view of the stacked structure of FIG. 3 in which up to the first protective layer 160 is formed. FIG. 7B is a cross-sectional view including the anode and the opening of the emission part. The cross-sectional structure illustrated in FIG. 7B is a cross-section taken along line A-A′ in FIG. 7A. FIG. 8 is a cross-sectional view illustrating a partial area around the fourth node of the display apparatus according to an embodiment of the present disclosure. In FIGS. 7A and 7B, some configurations that are not directly related to the features of the present disclosure are omitted in some circuit areas SP1CA, SP2CA and SP3CA of a pixel driving circuit.

Referring to FIGS. 7A, 7B, and 8, an auxiliary capacitor Cs may be formed to overlap the emission part of a red first sub-pixel SP1, which may be located below a gate wire GL supplying a third scan signal scan3[n]. The auxiliary capacitor Cs may connect the fourth node N4 and the fifth node N5. The fourth node N4 connected to the auxiliary capacitor Cs may be connected to an anode of a light-emitting element (OLED). The fifth node N5 connected to the auxiliary capacitor Cs may be connected to the low-potential driving voltage line VSSL that supplies the low-potential driving voltage ELVSS. The auxiliary capacitor Cs may include a first auxiliary capacitor electrode Cs1 and a second auxiliary capacitor electrode Cs2.

Referring to FIGS. 4, 7A, and 7B, in the case of FIG. 4, the reset voltage line VARL_GB and the reset voltage line VARL_R are arranged in an separated anode reset voltage VAR structure, but in the cases of FIGS. 7A and 7B, only one second common reset voltage line 122 is arranged, thereby creating the necessary room to form an auxiliary capacitor Cs. In a limited space, one of the first auxiliary capacitor electrode Cs1 and the second auxiliary capacitor electrode Cs2 of the auxiliary capacitor Cs may be formed as an electrode in the same layer as the gate wire GL. However, if the distance between the gate wire GL and the auxiliary capacitor Cs is too close during the process, the auxiliary capacitor Cs and the gate wire GL may be connected. Therefore, in order to maintain a constant gap between the auxiliary capacitor Cs and the gate wire GL, the width of a portion of the gate wires GL located above the auxiliary capacitor Cs may be formed narrower than the width of other areas. In addition, contact portions of the connection electrodes CE connected to the auxiliary capacitor Cs may be located above and below some of the narrow gate wires GL.

Referring to FIGS. 7A and 7B, the electrode patterns of the first auxiliary capacitor electrode Cs1 and the second auxiliary capacitor electrode Cs2 forming the auxiliary capacitor Cs may be overlapped with the bias voltage wire VobsL, or may be overlapped with the bias voltage wire VobsL and the second common reset voltage line 122. In addition, the electrode patterns of the first auxiliary capacitor electrode Cs1 and the second auxiliary capacitor electrode Cs2 may be overlapped with the emission part.

Referring to FIG. 8, the display panel 100 may include the element substrate 105, the buffer film 110, the first gate insulating film 212, a interlayer insulating film 214, the first protective film 130, the fourth insulating film 224, the second protective film 150, the first protective layer 160, the second protective layer 170, a first connecting electrode CE1, a second connecting electrode CE2, a third connecting electrode CE3, a fourth connecting electrode CE4, a fifth connecting electrode CE5, the auxiliary capacitor Cs, the anode 610, the emission layer 620, and the cathode 630 of the light-emitting element 600.

Referring to FIGS. 7A, 7B, and 8, the auxiliary capacitor Cs may include the first auxiliary capacitor electrode Cs1 and the second auxiliary capacitor electrode Cs2. Through the connecting electrodes CE, the auxiliary capacitor Cs may connect the fourth node N4 and the fifth node N5.

The first auxiliary capacitor electrode Cs1 may be connected to the fourth node N4 of the anode 610 of the light-emitting element 600 through the connecting electrode 1 CE1, the connecting electrode 2 CE2, the connecting electrode 3 CE3, and the connecting electrode 4 CE4.

The connecting electrode 1 CE1 may be arranged between the first protective layer 160 and the second protective layer 170, and may be formed of the same material or by the same process as the intermediate electrode 510. The connecting electrode 2 CE2 and the connecting electrode 4 CE4 may be arranged on the second protective film 150, and may be formed of the same material or by the same process as the second source electrode 225 and the second drain electrode 226. The connecting electrode 3 CE3 may be arranged on the fourth insulating film 224, and may be formed of the same material or by the same process as the second gate electrode 223. The connection electrode 3 CE3 may be formed to intersect the gate wire GL, as illustrated in FIGS. 7A and 7B, and may be arranged in a direction perpendicular to the direction of the gate wire GL. For example, the anode 610 of the light-emitting element 600 may be connected to the connection electrode 1 CE1 by penetrating the second protective layer 170, and the connection electrode 1 CE1 may be connected to the connection electrode 2 CE2 by penetrating the first protective layer 160. The connection electrode 2 CE2 and the connection electrode 4 CE4 may be connected to the connection electrode 3 CE3 by penetrating the second protective film 150. The connection electrode 4 CE4 may be connected to the first auxiliary capacitor electrode Cs1 by penetrating the first protective film 130, the fourth insulating film 224, and the second protective film 150. As illustrated in FIGS. 7A and 7B, since the gate line GL is located between the connecting electrode 4 CE4, which is connected to the first auxiliary capacitor electrode Cs1, and the connection electrode 2 CE2 and the connection electrode 4 CE4 may be connected via connecting electrode 3 CE3. This arrangement increases panel design flexibility and improves manufacturing convenience. In another embodiment, in order to connect the connection electrode 2 CE2 and the connection electrode 4 CE4 formed in the same layer, they may be directly connected without going through a connecting electrode of another layer.

The second auxiliary capacitor electrode Cs2 is another electrode of the auxiliary capacitor Cs and may be connected to the fifth node N5 of the low-potential driving voltage line VSSL that supplies the low-potential driving voltage ELVSS. The low-potential driving voltage line VSSL is connected to the power supply 500 and may supply the low-potential driving voltage ELVSS to a plurality of sub-pixels SP1, SP2 and SP3. The low-potential driving voltage line VSSL may overlap each sub-pixel and may be arranged in a vertical direction, and the low-potential driving voltage line VSSL may be formed by a low-potential driving voltage electrode VSSE. The low-potential driving voltage electrode VSSE may be arranged on the first protective layer 160 and may be formed of the same material or by the same process as the intermediate electrode 510. The connecting electrode 5 CE5 may be arranged on the second protective film 150, and may be formed of the same material or by the same process as the second source electrode 225 and the second drain electrode 226. For example, the low-potential driving voltage electrode VSSE may be connected to the connecting electrode 5 CE5 by penetrating the first protective layer 160. The connecting electrode 5 CE5 may be connected to the second auxiliary capacitor electrode Cs2 by penetrating the interlayer insulating film 214, the first protective film 130, the fourth insulating film 224, and the second protective film 150.

The first auxiliary capacitor electrode Cs1 may be formed in the same layer as the auxiliary layer 232, and the second auxiliary capacitor electrode Cs2 may be formed in the same layer as the first gate electrode 213. The first auxiliary capacitor electrode Cs1 and the second auxiliary capacitor electrode Cs2 may be arranged to overlap each other, and each electrode pattern may be formed and arranged in a similar shape. For example, each of the first auxiliary capacitor electrode Cs1 and the second auxiliary capacitor electrode Cs2 patterns may be arranged to overlap each other in the same horizontal direction as the arrangement direction of the gate wire GL forming the scan line located in the display panel 100, and the shapes of the two electrode patterns may be similar. The size of the auxiliary capacitor electrodes may be adjusted according to the capacitor capacitance in order to provide the capacitor capacitance similar to that of different color.

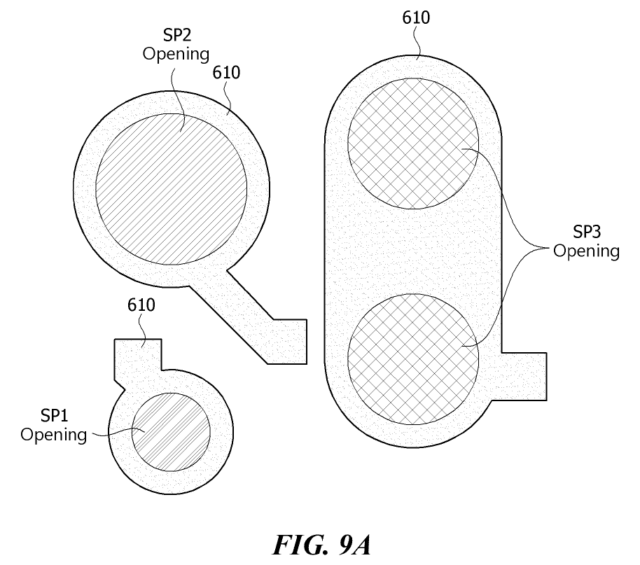

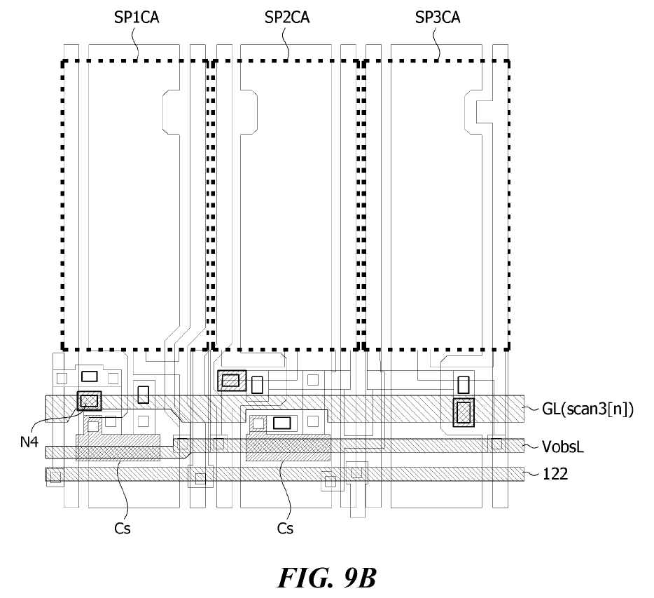

FIGS. 9A and 9B are plan views of a plurality of sub-pixels SP1, SP2 and SP3 according to another embodiment of the present disclosure. FIG. 9A shows anode electrodes and opening areas of a plurality of sub-pixels SP1, SP2 and SP3, and FIG. 9B is a plan view of the stacked structure of FIG. 3, in which up to the first protective layer 160 is formed. FIGS. 9A and 9B are identical in configuration to FIGS. 7A and 7B except for, among the configurations of the plurality of sub-pixels SP1, SP2 and SP3, the openings of the first and second sub-pixels SP1 and SP2 of red and green and the corresponding auxiliary capacitor Cs, so a detailed description thereof will be omitted. In FIGS. 9A and 9B, some configurations that are not directly related to the features of the present disclosure are omitted in some circuit areas SP1CA, SP2CA and SP3CA.

Referring to FIG. 9A, among the plurality of sub-pixels SP1, SP2 and SP3, the area sizes of the openings of the emission parts of the first and second sub-pixels SP1 and SP2 of red and green are similar, and are smaller than the area size of the opening of the emission part of the third sub-pixel SP3 of blue. Therefore, in order to improve the low gray-scale image quality, the single common reset voltage line 122 may be formed in the pixel P, and, as shown in FIG. 9B, auxiliary capacitors Cs may be formed in each of the first and second sub-pixels SP1 and SP2 of red and green, respectively.

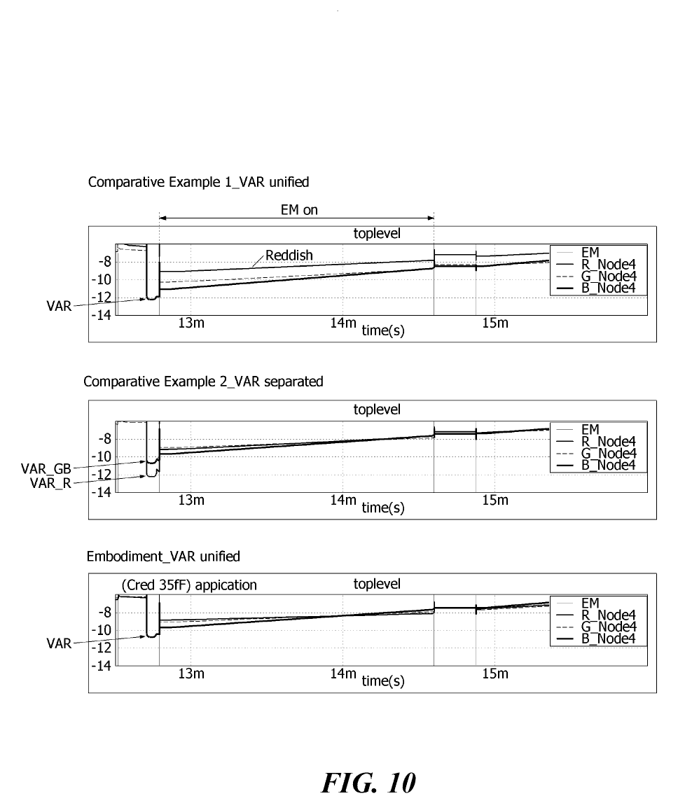

FIG. 10 is a simulation result for driving voltages according to Comparative Example 1, Comparative Example 2, and the embodiment of the present disclosure. Specifically, Comparative Example 1 is a unified anode reset voltage VAR structure that supplies the same anode reset voltage VAR to all sub-pixels of different colors, and Comparative Example 2 is a separated anode reset voltage VAR structure that supplies different anode reset voltages VAR to sub-pixels of different colors. The embodiment of the present disclosure is a structure in which the same anode reset voltage VAR is supplied to all sub-pixels of different colors according to one embodiment of the present disclosure, and an auxiliary capacitor Cs is arranged between the anode and a low-potential voltage line in a sub-pixel having a smaller aperture ratio than other sub-pixels.

The low-potential driving voltage line may be interpreted as a power supply line directly connected to the cathode electrode of the light-emitting element (OLED), a power supply line supplying the voltage for the cathode electrode, a constant voltage node, or the like. Accordingly, the fact that the auxiliary capacitor Cs is arranged between the anode electrode of the light-emitting element (OLED) and the low-potential voltage line may be electrically equivalent to the fact that the auxiliary capacitor Cs is arranged between the anode electrode and the cathode electrode of the light-emitting element (OLED).

In Comparative Example 1, which supplies the same anode reset voltage VAR to sub-pixels of different colors, the voltage of the red sub-pixel among the sub-pixels of different colors may increase quickly during the emission part turn-on period, and then reach the emission voltage earlier than the sub-pixels of the other two colors and emits light. Therefore, the screen may appear red in a low gray-scale image.

In Comparative Example 2 that supplies different anode reset voltages VAR to the sub-pixels, the anode may be reset with the optimal voltage for each sub-pixel, so that the voltage rising speeds of the sub-pixels of different colors during the emission part turn-on period may be similar, and thus the sub-pixels may reach their emission voltages similarly.

In the embodiment of the present disclosure, as in Comparative Example 1, the same anode reset voltage VAR may be supplied to sub-pixels of different colors; however, the auxiliary capacitor Cs added to the red sub-pixel may provide an effect similar to the capacitor capacitance of the green sub-pixel and the blue sub-pixel, so that, as in Comparative Example 2 which resets the anode with the optimal voltage for each sub-pixel, the voltage rising speeds of the sub-pixels may be similar, and thus the sub-pixels may reach their emission voltages similarly.

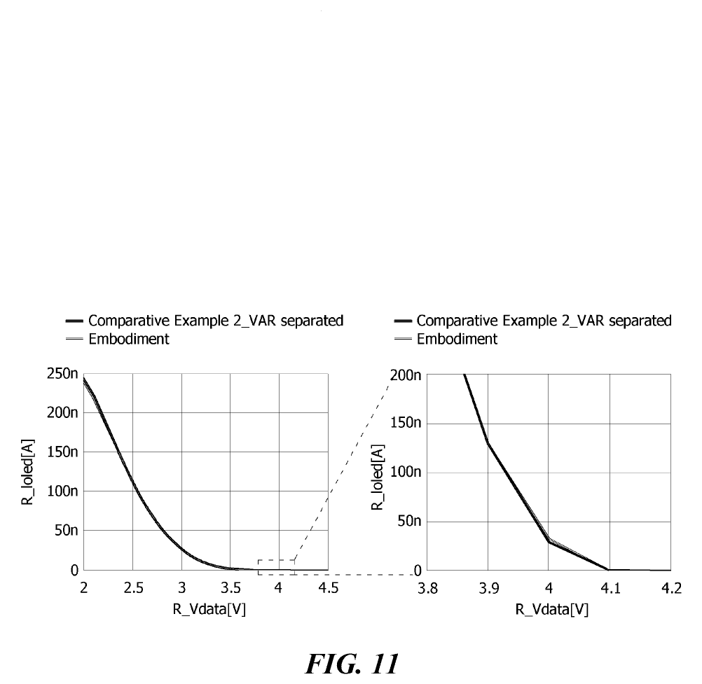

FIG. 11 is a simulation result comparing data ranges of Comparative Example 2 and the embodiment of the present disclosure to confirm changes in low gray-scale image quality. In order to confirm the change in low gray-scale image quality due to the actual increase in capacitor capacitance by the auxiliary capacitor Cs added according to one embodiment of the present disclosure, the data ranges of Comparative Example 2 and the embodiment of the present disclosure were compared, and it may be confirmed that the data ranges of Comparative Example 2 and the embodiment are similar.

Accordingly, in the display panel 100 according to one embodiment of the present disclosure, it is permitted that the anode may be reset with the optimal voltage for each sub-pixel. In case that the same anode reset voltage is supplied to all sub-pixels of different colors, there is a problem that degradation occurs in the electro-optical item due to the difference in capacitor capacitance for each color and the differences in lifespan and emission area. Considering this issue, the display panel 100 according to one embodiment of the present disclosure may supply different reset voltages for each red sub-pixel, green sub-pixel, and blue sub-pixel to reset the anode with the optimal voltage for each sub-pixel, thereby improving the emission characteristic.

When different reset voltage lines are connected to supply different reset voltages to the red sub-pixel, the green sub-pixel, and the blue sub-pixel of the display apparatus, the reset voltage line for supplying each reset voltage within the display area may make the design difficult, and may increase capacitance with other signal lines, resulting in a problem of deteriorating display quality. In consideration of this, in the display panel 100 according to one embodiment of the present disclosure, the red sub-pixel, the green sub-pixel, and the blue sub-pixel may be connected by the single common reset voltage line 120. Accordingly, the display panel 100 according to one embodiment of the present disclosure may supply different reset voltages to each sub-pixel with the single common reset voltage line 120, and thus may supply an optimal reset voltage to each sub-pixel without adding a separate voltage line within the display area.

When an initialization voltage for initializing a driving transistor and a reset voltage for resetting an anode of a light-emitting element are supplied to a red sub-pixel, a green sub-pixel, and a blue sub-pixel of a display apparatus, a line for supplying an initialization voltage and a reset voltage line for separately supplying a reset voltage within a display area may make the design difficult, and may increase capacitance with other signal lines, resulting in a problem of deteriorating display quality. In consideration of this, in the display panel 100 according to one embodiment of the present disclosure, the single common reset voltage line 121 and 122 may be connected to supply the initialization voltage and the reset voltage to the red sub-pixel, the green sub-pixel, and the blue sub-pixel, and a reset voltage most similar to the initialization voltage among the reset voltages may be supplied to the common reset voltage line 120. In this case, it may be lower than the reset voltage for the corresponding sub-pixel. Accordingly, by arranging an auxiliary capacitor Cs between the anode and the low-potential voltage line, the auxiliary capacitor connected in parallel with the light-emitting element ED may increase the capacitance, so that the supplied reset voltage may be increased to compensate for the corresponding sub-pixel.

The display apparatus according to one or more embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a notebook, a monitor, a camera, a camcorder, a home appliance, and the like. In addition, the display device according to one or more embodiments of the present disclosure can be applied to an organic light-emitting lighting device or an inorganic light-emitting lighting device.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and can be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a display panel including a display area in which a plurality of sub-pixels of different colors are arranged, and a non-display area;
a light-emitting element arranged in each of the plurality of sub-pixels and including an anode and a cathode; and
a common reset voltage line connected to the anode to transmit a common reset voltage to each of the plurality of sub-pixels,
wherein the plurality of sub-pixels comprise an auxiliary capacitor connected between the anode and the cathode.

2. The display apparatus of claim 1, wherein at least a portion of the common reset voltage line is disposed in the non-display area.

3. The display apparatus according to claim 2, wherein the common reset voltage line comprises:
at least one first common reset voltage line arranged on at least one of sides of the display panel in the non-display area; and
a plurality of second common reset voltage lines connected to the at least one first common reset voltage line , extending to the display area, and connected to the plurality of sub-pixels.

4. The display apparatus according to claim 1, wherein each of the plurality of sub-pixels comprises one or more transistors, a driving transistor, and a storage capacitor.

5. The display apparatus according to claim 4, wherein a semiconductor layer of the driving transistor and a semiconductor layer of the one or more transistors are formed of an oxide semiconductor layer or a low temperature poly-silicon semiconductor layer.

6. The display apparatus according to claim 5, wherein the driving transistor is connected to a second node,
the one or more transistors comprise:
a first transistor connected between the second node and a third node;
a second transistor connected to a first node;
a third transistor connected to the first node;
a fourth transistor connected between the third node and a fourth node;
a fifth transistor connected to the second node;
a sixth transistor connected to the fourth node; and
a seventh transistor connected to the first node.

7. The display apparatus according to claim 6, wherein the storage capacitor is connected between a high potential driving voltage terminal and the second node.

8. The display apparatus according to claim 6, wherein the light-emitting element is connected between the fourth node and a low voltage driving voltage terminal.

9. The display apparatus according to claim 1, wherein the auxiliary capacitor is connected between the anode and the cathode of a sub-pixel having the smallest aperture ratio among the plurality of sub-pixels.

10. The display apparatus according to claim 1, wherein the auxiliary capacitor is connected between the anode and the cathode of at least one of the plurality of sub-pixels, excluding a sub-pixel having a largest aperture ratio among the plurality of sub-pixels.

11. The display apparatus according to claim 10, wherein at least two sub-pixels of different colors among the plurality of sub-pixels comprise the auxiliary capacitor connected to the at least two sub-pixels of different colors.

12. The display apparatus according to claim 2, wherein the display panel comprises:
a substrate;
a plurality of insulating layers arranged on the substrate;
a second auxiliary capacitor electrode arranged on the plurality of insulating layers;
an insulating film arranged on the second auxiliary capacitor electrode; and
a first auxiliary capacitor electrode arranged on the insulating film to overlap the second auxiliary capacitor electrode.

13. The display apparatus according to claim 12, further comprising a first connection electrode connected to the first auxiliary capacitor electrode and the anode, and a second connection electrode connected to the second auxiliary capacitor electrode and a low-potential power supply voltage electrode.

14. The display apparatus according to claim 13, further comprising:
a plurality of protective films arranged on the first auxiliary capacitor electrode, wherein the second connection electrode is arranged on the plurality of protective films;
a first protective layer arranged on the second connection electrode, wherein the first connection electrode and the low-potential power voltage electrode are arranged on the first protective layer; and
a second protective layer arranged on the first connection electrode and the low-potential power voltage electrode, wherein the anode is arranged on the second protective layer.

15. The display apparatus according to claim 13, wherein the first auxiliary capacitor electrode and the second auxiliary capacitor electrode have a same electrode pattern shape and overlap each other.

16. The display apparatus according to claim 1, further comprising:
a gate driver configured to supply a first scan signal, a second scan signal, a third scan signal, a fourth scan signal, and an emission signal to a plurality of gate wires connected to the plurality of sub-pixels,
wherein the auxiliary capacitor is arranged below a gate wire supplying the third scan signal, which is located within the display panel.

17. The display apparatus according to claim 16, wherein a width of a first portion of the gate wire for supplying the third scan signal is narrower than a width of other portions of the gate wire.

18. The display apparatus according to claim 17, wherein the auxiliary capacitor is arranged below the first portion of the gate wire.

19. The display apparatus according to claim 6, wherein the auxiliary capacitor overlaps a bias voltage line which extends in a horizontal direction in the display area and is configured to provide a bias voltage to the first node of the seventh transistor.

20. The display apparatus according to claim 1, wherein the auxiliary capacitor overlaps an emission part of the light-emitting element.
